(19) United States
(12) Patent Application Publication
(10) Pub. No.: US 2010/0084673 A1
(43) Pub. Date: Apr. 8, 2010

(54) Light-emitting semiconductor packaging structure without wire bonding

(76) Inventor: Kwun-Yao HO, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/457,273

(22) Filed: Jun. 5, 2009

(30) Foreign Application Priority Data
Oct. 6, 2008 (TW) 097210245

(51) Int. Cl. H01L 33/00

(52) U.S. Cl. 257/98; 257/E33.056

(57) ABSTRACT

A light-emitting semiconductor packaging structure without wire bonding, including a heat conduction board, a light-emitting semiconductor chip bonded on the heat conduction board and a lead frame positioned around the chip. The lead frame has at least one connection section extending to upper side of the chip to connect with a conductive protruding block adhered to an active surface of the chip. The conductive protruding block is bonded with the chip and the connection section of the lead frame by larger area so that the heat conduction area is increased to enhance heat dissipation effect for the chip. It is unnecessary to save upward and outward extension room for wire bonding so that the volume and thickness of the packaging structure are minified. The chip is received in a cavity of the lead frame to form a lightweight and miniaturized heat dissipation packaging structure.

### BACKGROUND OF THE INVENTION

The present invention is related to a semiconductor packaging structure, and more particularly to a light-emitting semiconductor packaging structure without wire bonding, which has higher heat dissipation efficiency.

A conventional incandescent bulb has a bulb filament. When great current flows through the bulb filament, the bulb filament is heated to emit light. Such incandescent bulb consumes high energy. Recently, various light-emitting semiconductor materials have been developed to substitute for the conventional incandescent bulbs. The semiconductor materials emit light when holes and electrons are recombined to release energy. Light-emitting diode is a typical example of the light-emitting semiconductor. Only little current is required for energizing the light-emitting diode to emit high-intensity light. The light-emitting semiconductor has the advantages of small volume, long lifetime, low drive voltage, low power consumption, fast reaction rate, excellent antishock ability, good monochromaticity, etc. Therefore, the light-emitting semiconductor has been more and more emphasized and widely applied to the fields of illumination, display backlight sources, etc.

However, currently, all the light-emitting semiconductor manufacturers face a major problem of heat dissipation. This is because when the light-emitting semiconductors work to emit light, the light-emitting semiconductors will at the same time generate high heat, especially the high-brightness light-emitting semiconductors or arrayed light-emitting semiconductors. In the case that the heat generated by the light-emitting semiconductors is not properly removed and dissipated, the heat will accumulate to result in continuous rise of temperature. This will deteriorate the lighting efficiency and quality of the light-emitting semiconductors. Therefore, heat dissipation efficiency has become a highly determining factor of working performance of the light-emitting semiconductor.

It is known that the package pattern of the light-emitting semiconductor critically affects the heat dissipation capability of the light-emitting semiconductor. FIG. 1 shows a conventional light-emitting diode packaging structure without wire bonding for more efficiently dissipating heat. In such structure, the LED chip 100 is die-bonded in a U-shaped cavity 111 of the silicon crystal frame 110 in flip chip format to form a flip-chip package module. The module is then packaged on an aluminum-made circuit board 120, which provides heat dissipation effect, with an outer surface or an electrode 112 of the flip chip attached to the circuit board 120. Accordingly, the heat generated by the chip can be directly conducted and dissipated from the outer surface of the flip chip at good efficiency. In this case, the LED can tolerate greater working current to enhance light intensity. However, in such flip-chip format, the light needs to penetrate through the transparent substrate 113 of the chip. This results in photoresistance problem, which needs to be overcome.

### SUMMARY OF THE INVENTION

It is therefore a primary object of the present invention to provide a light-emitting semiconductor packaging structure without wire bonding. The packaging structure not only is free from the problems derived from the wire bonding process in the early-stage chip, but also is free from the photoresistance problem due to flip-chip format. The light-emitting semiconductor chip is connected to the heat conduction board by means of the connection between the conductive protruding blocks and the connection sections of the lead frame instead of the conventional wire bonding. The conductive protruding blocks are bonded with the chip and the connection sections of the lead frame by larger area so that the heat conduction area is increased to provide better heat dissipation effect for the chip.

To achieve the above and other objects, the light-emitting semiconductor packaging structure without wire bonding of the present invention includes a heat conduction board, a light-emitting semiconductor (or light-emitting diode) chip and a lead frame. The light-emitting semiconductor chip is disposed on the heat conduction board inside an internal cavity of the lead frame. The light-emitting semiconductor chip has an active surface and at least one conductive protruding block disposed on the active surface. The lead frame is positioned on an upper side of the heat conduction board around the light-emitting semiconductor chip. The lead frame has at least one connection section extending to upper side of the active surface of the light-emitting semiconductor chip to connect with the conductive protruding block. The heat generated by the chip can be directly conducted from the conductive protruding block to the connection section. Accordingly, the heat generated by the upper active surface of the chip in non-flip-chip format can be directly conducted to the connection section with larger heat conduction area. This simplifies the manufacturing process. Moreover, the heat conduction area of the conductive protruding block is much larger than that of wire bonding so that the heat dissipation area is greatly increased to enhance heat dissipation effect.

The present invention can be best understood through the following description and accompanying drawings wherein:

### BRIEF DESCRIPTION OF THE DRAWINGS

FIG. 1 is a sectional view of a flip-chip packaging structure of a conventional light-emitting diode;

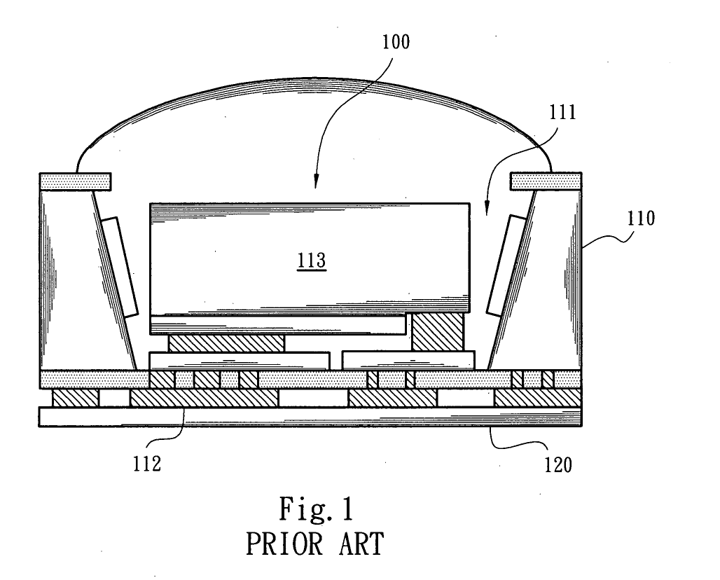

FIG. 2 is a sectional view of a first embodiment of the light-emitting semiconductor packaging structure without wire bonding of the present invention;

FIG. 3 is a sectional view of a second embodiment of the light-emitting semiconductor packaging structure without wire bonding of the present invention; and

FIG. 4 is a sectional view of a third embodiment of the light-emitting semiconductor packaging structure without wire bonding of the present invention.

### DETAILED DESCRIPTION OF THE PREFERRED EMBODIMENTS

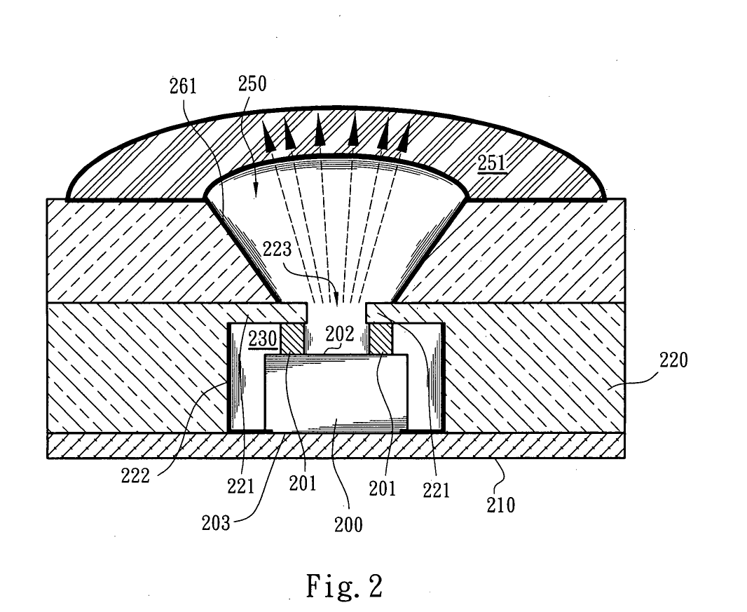

Please refer to FIG. 2. According to a first embodiment, the light-emitting semiconductor (or light-emitting diode) packaging structure without wire bonding of the present invention includes a heat conduction board 210, a light-emitting semiconductor chip 200 and a lead frame 220. The light-emitting semiconductor chip 200 is disposed on the heat conduction board 210 inside an internal cavity 230 of the lead frame 220. The heat conduction board 210 can be a copper board or an aluminum board with good heat dissipation capability or a substrate coated with nickel or tin or a substrate under which a heat sink is arranged. In the case that the light-emitting semiconductor chip 200 has a bottom face as an electrode, the heat conduction board 210 can be also a power supply electrode. The light-emitting semiconductor chip has an active surface 202 proximal to the active area of the chip 200 and a non-active surface 203 (back face) distal from the active area of the chip 200. The non-active surface 203 attaches to the heat conduction board 210. In other words, the light-emitting semiconductor is bonded to the heat conduction board 210 in non-flip-chip format, whereby the light is emitted from the active surface 202 of the chip 200 distal from the heat conduction board 210. Accordingly, the photoresistance problem caused by the substrate of the chip can be obviated.

At least one conductive protruding block 201 is disposed on the active surface 202 of the light-emitting semiconductor chip 200. The conductive protruding block 201 is made of a metal, an alloy or a conductor material, such as copper/nickel/gold alloy, copper/tin alloy, copper/oxidation protection layer, nickel/gold alloy, palladium, etc. The light-emitting semiconductor chip 200 is bonded to the heat conduction board 210 by means of soldering paste, tin ball, silver glue, tin or conductive adhesive. Alternatively, the light-emitting semiconductor chip 200 can be bonded to the heat conduction board 210 by means of thermocompression bonding or ultrasonic thermocompression bonding.

The lead frame 220 is positioned on an upper side of the heat conduction board 210 around the light-emitting semiconductor chip 200. The lead frame 220 is coated with tin, silver, palladium or nickel/gold alloy. The lead frame 220 has at least one connection section 221 extending to upper side of the light-emitting semiconductor chip 200 with at least one projection opening 223 reserved. The connection section 221 is coated with tin, aluminum or silver to enhance light reflection effect. FIG. 2 shows that the lead frame 220 has, but not limited to, at least two connection sections 221. The connection sections 221 are adapted to the conductive protruding blocks 201 on the active surface of the light-emitting semiconductor chip 200. Accordingly, the light-emitting semiconductor chip 200 can be connected with the connection sections 221 by means of the connection between the conductive protruding blocks 201 on the light-emitting semiconductor chip 200 and the connection sections 221 of the lead frame 220 instead of the conventional wire bonding. Such manufacturing process is easier than the conventional wire bonding process. Moreover, the conductive protruding blocks 201 are bonded with the light-emitting semiconductor chip 200 and the connection sections 221 by much larger bonding area than the conventional wire bonding process so that the heat conduction area is greatly increased to enhance heat dissipation effect as a whole.

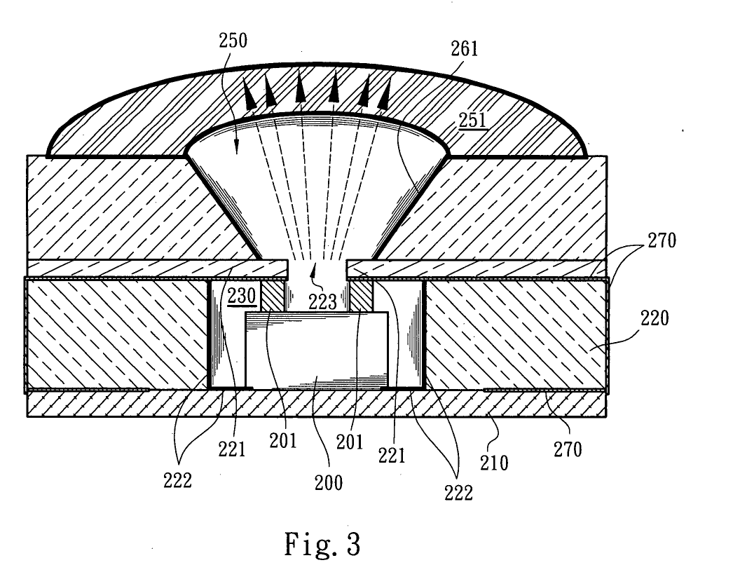

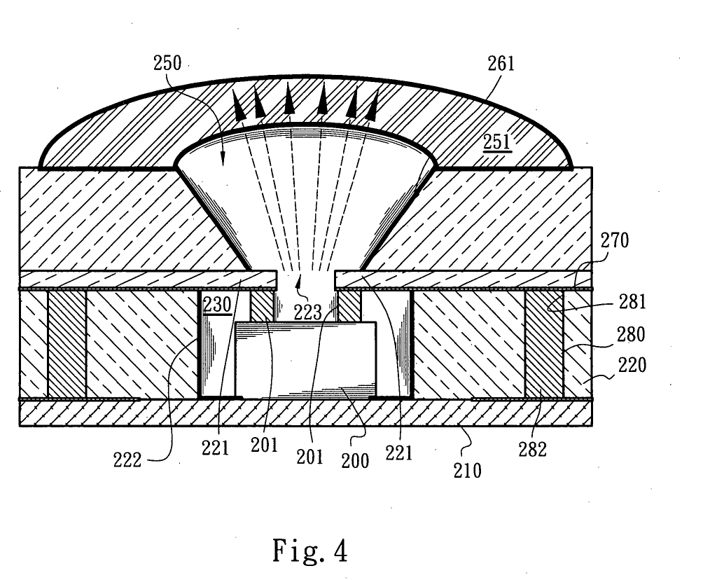

In the case that the lead frame 220 is made of dielectric material, it is necessary to additionally lay out wires as shown in FIGS. 3 and 4. FIG. 3 shows a second embodiment of the present invention, in which multiple leads 270 are laid on the upper and lower surfaces of the lead frame 220. A reflection cup 250 is disposed on upper side of the lead frame 220. The surface of the reflection cup 250 is coated with a metal reflection layer 261 made of tin, silver, aluminum or any other material with high light reflectivity. On the other hand, the inner surface of the cavity 230, that is, the inner surface of the lead frame 220 and the surface of the heat conduction board 210, are coated with a reflection layer 222 made of tin, silver or aluminum. The reflection layer 222 further enhances the reflection effect of the inner surface of the cavity 230 and promotes the intensity of light emitted through the projection opening 223. A lens 251 can be bonded to upper side of the reflection cup by means of packaging resin. Fluorescent powder layers can be distributed in the packaging resin. Alternatively, the active surface 202 of the upper side of the light-emitting semiconductor chip 200 can be directly painted with a material of fluorescent powder. Under such circumstance, the light emitted from the light-emitting semiconductor chip 200 can energize the fluorescent powder to emit various colors of visible light. Furthermore, the lens 251 serves to converge the light emitted from the light-emitting semiconductor chip 200.

In FIG. 3, the leads 270 of the upper surface of the lead frame 220 directly extend to one side of the lead frame 220 and then to lower side thereof to connect with the leads 270 of the lower surface of the lead frame 220. Alternatively, FIG. 4 shows a third embodiment of the present invention, in which the lead frame 220 is formed with at least one internal passage 281 extending through the lead frame 220 from the upper surface of the lead frame to the lower surface thereof. A conductive material 282 (such as copper material) is filled in the passage 281 to form a conductive path 280 connected between the leads 270 of the upper and lower surfaces of the lead frame 220.

In conclusion, the connection sections 221 of the lead frame 220 extend to the upper side of the light-emitting semiconductor chip 200 for directly connecting with the conductive protruding blocks 201 on the active surface of the light-emitting semiconductor chip 200. Accordingly, the conventional precise bonding process of two ends of the wire is omitted. In this case, not only the problems derived from the wire bonding process can be avoided, but also the processing and manufacturing procedures become easier. Moreover, the conductive protruding blocks 201 are bonded with the light-emitting semiconductor chip 200 and the connection sections 221 of the lead frame 220 by larger area so that the heat conduction area is increased to greatly enhance heat dissipation effect as a whole.

The above embodiments are only used to illustrate the present invention, not intended to limit the scope thereof. Many modifications of the above embodiments can be made without departing from the spirit of the present invention.

What is claimed is:

1. A light-emitting semiconductor packaging structure without wire bonding, comprising:
a heat conduction board;
a light-emitting semiconductor chip disposed on the heat conduction board, the light-emitting semiconductor chip having an active surface distal from the heat conduction board, at least one conductive protruding block being disposed on the active surface; and
a lead frame positioned on an upper side of the heat conduction board around the light-emitting semiconductor chip, the lead frame having at least one connection section extending to upper side of the light-emitting semiconductor chip to connect with the conductive protruding block, the lead frame being formed with a projection opening distal from the heat conduction board.

2. The light-emitting semiconductor packaging structure without wire bonding as claimed in claim 1, wherein a reflection cup is disposed on the lead frame distal from the heat conduction board.

3. The light-emitting semiconductor packaging structure without wire bonding as claimed in claim 2, wherein a surface of the reflection cup is coated with a reflection layer.

4. The light-emitting semiconductor packaging structure without wire bonding as claimed in claim 1, wherein a cavity is defined between an inner side of the lead frame, an upper surface of the heat conduction board and the light-emitting semiconductor chip.

5. The light-emitting semiconductor packaging structure without wire bonding as claimed in claim 4, wherein a reflection layer is disposed on an inner surface of the cavity.

6. The light-emitting semiconductor packaging structure without wire bonding as claimed in claim 2, wherein a cavity is defined between an inner side of the lead frame, an upper surface of the heat conduction board and the light-emitting semiconductor chip.

7. The light-emitting semiconductor packaging structure without wire bonding as claimed in claim 1, wherein a lens is bonded to upper side of the reflection cup in alignment with the projection opening by means of packaging resin.

8. The light-emitting semiconductor packaging structure without wire bonding as claimed in claim 4, wherein a lens is bonded to upper side of the reflection cup in alignment with the projection opening by means of packaging resin.

9. The light-emitting semiconductor packaging structure without wire bonding as claimed in claim 1, wherein the heat conduction board is a substrate under which a heat sink is arranged.

10. The light-emitting semiconductor packaging structure without wire bonding as claimed in claim 4, wherein the heat conduction board is a substrate under which a heat sink is arranged.

11. The light-emitting semiconductor packaging structure without wire bonding as claimed in claim 7, wherein the heat conduction board is a substrate under which a heat sink is arranged.

12. The light-emitting semiconductor packaging structure without wire bonding as claimed in claim 1, wherein leads are laid on upper and lower surfaces of the lead frame made of dielectric material, the lead frame distal from and proximal to the heat conduction board, the leads laid on the upper surface being connected to the leads laid on the lower surface.

13. The light-emitting semiconductor packaging structure without wire bonding as claimed in claim 12, wherein the leads laid on the upper and lower surfaces of the lead frame extend to one side of the lead frame and connect with each other.

14. The light-emitting semiconductor packaging structure without wire bonding as claimed in claim 12, wherein at least one conductive path is formed through the lead frame between the upper and lower surfaces thereof for connecting the leads laid on the upper and lower surfaces of the lead frame.

15. The light-emitting semiconductor packaging structure without wire bonding as claimed in claim 14, wherein the lead frame is formed with at least one internal passage extending through the lead frame from the upper surface to the lower surface of the lead frame, a conductive material being filled in the passage to form the conductive path.

16. The light-emitting semiconductor packaging structure without wire bonding as claimed in claim 4, wherein leads are laid on upper and lower surfaces of the lead frame made of dielectric material, the lead frame distal from and proximal to the heat conduction board, the leads laid on the upper surface being connected to the leads laid on the lower surface.

17. The light-emitting semiconductor packaging structure without wire bonding as claimed in claim 16, wherein the leads laid on the upper and lower surfaces of the lead frame extend to one side of the lead frame and connect with each other.

18. The light-emitting semiconductor packaging structure without wire bonding as claimed in claim 16, wherein at least one conductive path is formed through the lead frame between the upper and lower surfaces thereof for connecting the leads laid on the upper and lower surfaces of the lead frame.

19. The light-emitting semiconductor packaging structure without wire bonding as claimed in claim 18, wherein the lead frame is formed with at least one internal passage extending through the lead frame from the upper surface to the lower surface of the lead frame, a conductive material being filled in the passage to form the conductive path.

20. The light-emitting semiconductor packaging structure without wire bonding as claimed in claim 7, wherein leads are laid on upper and lower surfaces of the lead frame made of dielectric material, the lead frame distal from and proximal to the heat conduction board, the leads laid on the upper surface being connected to the leads laid on the lower surface.

21. The light-emitting semiconductor packaging structure without wire bonding as claimed in claim 9, wherein leads are laid on upper and lower surfaces of the lead frame made of dielectric material, the lead frame distal from and proximal to the heat conduction board, the leads laid on the upper surface being connected to the leads laid on the lower surface.

22. The light-emitting semiconductor packaging structure without wire bonding as claimed in claim 1, wherein the light-emitting semiconductor chip is a light-emitting diode chip.

23. The light-emitting semiconductor packaging structure without wire bonding as claimed in claim 4, wherein the light-emitting semiconductor chip is a light-emitting diode chip.

24. The light-emitting semiconductor packaging structure without wire bonding as claimed in claim 7, wherein the light-emitting semiconductor chip is a light-emitting diode chip.

25. The light-emitting semiconductor packaging structure without wire bonding as claimed in claim 9, wherein the light-emitting semiconductor chip is a light-emitting diode chip.

26. The light-emitting semiconductor packaging structure without wire bonding as claimed in claim 12, wherein the light-emitting semiconductor chip is a light-emitting diode chip.
